(19) United States
(12) Patent Application Publication
(10) Pub. No.: US 2025/0192123 A1
(43) Pub. Date: Jun. 12, 2025

(54) DISPLAY APPARATUS HAVING PIXEL DRIVING CIRCUIT

(71) Applicant: LG DISPLAY CO., LTD., Seoul (KR)

(72) Inventor: Sung Ju CHOI, Paju-si, Gyeonggi-do (KR)

(73) Assignee: LG DISPLAY CO., LTD., Seoul (KR)

(21) Appl. No.: 18/788,342

(22) Filed: Jul. 30, 2024

(30) Foreign Application Priority Data
Dec. 12, 2023 (KR) 10-2023-0179936

(51) Int. Cl. H01L 25/16; H01L 27/12; H01L 33/62

(52) U.S. Cl. CPC H01L 25/165; H10D 86/423; H10D 86/60; H10H 20/857

(57) ABSTRACT

A display apparatus includes a pixel driving circuit including a thin film transistor; and a light-emitting device electrically connected to the pixel driving circuit, wherein a gate of the thin film transistor includes a first sub-gate and a second sub-gate electrically connected to the first sub-gate, wherein the thin film transistor has a semiconductor pattern that includes a first sub-channel and a second sub-channel, which are disposed parallel to each other between a drain region and a source region, and wherein the second sub-gate overlapping the second sub-channel has a work-function greater than the first sub-gate overlapping the first sub-channel, thus increasing a driving current and improving reliability without decreasing a threshold voltage.

### CROSS-REFERENCE TO RELATED APPLICATION

This application claims the priority of Korean Patent Application No. 10-2023-0179936, filed on Dec. 12, 2023, which is hereby incorporated by reference in its entirety.

### BACKGROUND

### Field of the Disclosure

The present disclosure relates to a display apparatus in which a pixel driving circuit electrically connected to a light-emitting device is disposed in each pixel area.

### Description of the Background

Generally, a display apparatus provides an image to a user. For example, the display apparatus may include a plurality of light-emitting devices. Each of the light-emitting devices may emit light displaying a specific color. For example, each of the light-emitting devices may include at least one emission material layer between a first electrode and a second electrode.

Each of the light-emitting devices may be controlled by a pixel driving circuit. For example, the pixel driving circuit electrically connected to one of the light-emitting devices may be disposed in each pixel area of the display apparatus. The pixel driving circuit of each pixel area may supply a driving current corresponding to a data signal to the light-emitting device of the corresponding pixel area according to a gate signal for one frame. For example, the pixel driving circuit of each pixel area may include a driving thin film transistor generating the driving current corresponding to the data signal and at least one switching thin film transistor transmitting the data signal and/or the driving current.

A gray-scale of color realized in each pixel area may be determined by the driving current, which is generated by the driving thin film transistor of the corresponding pixel area. For example, the driving thin film transistor of each pixel area may have different electrical characteristics from the switching thin film transistor of the corresponding pixel area. Thus, in the display apparatus, a process of forming the pixel driving circuit in each pixel area may be complicated. Therefore, in the display apparatus, process efficiency may be deteriorated. And, in the display apparatus, quality of the image may be deteriorated due to a difference in characteristics of the pixel driving circuit in each pixel area.

### SUMMARY

Accordingly, the present disclosure is directed to a display apparatus that substantially obviates one or more problems due to limitations and disadvantages of the related art.

More specifically, the present disclosure is to provide a display apparatus capable of improving reliability of a pixel driving circuit in each pixel area.

The present disclosure is also to provide a display apparatus capable of minimizing deterioration of process efficiency and increasing a driving current generated by a driving thin film transistor of each pixel area.

Additional advantages and features of the disclosure will be set forth in part in the description which follows and in part will become apparent to those having ordinary skill in the art upon examination of the following or may be learned from practice of the disclosure. Other advantages of the disclosure may be realized and attained by the structure particularly pointed out in the written description and claims hereof as well as the appended drawings.

To achieve these and other advantages and in accordance with the present disclosure, as embodied and broadly described herein, a display apparatus includes a pixel driving circuit including a thin film transistor; and a light-emitting device electrically connected to the pixel driving circuit, wherein a gate of the thin film transistor includes a first sub-gate and a second sub-gate electrically connected to the first sub-gate, wherein the thin film transistor has a semiconductor pattern that includes a first sub-channel and a second sub-channel, which are disposed parallel to each other between a drain region and a source region, and wherein the second sub-gate overlapping the second sub-channel has a work-function greater than the first sub-gate overlapping the first sub-channel.

In another aspect of the present disclosure, a display apparatus includes a first thin film transistor disposed on a pixel area of a device substrate, wherein the first thin film transistor includes a first semiconductor pattern and a first gate electrode; a second thin film transistor disposed on the pixel area of the device substrate, wherein the second thin film transistor includes a second semiconductor pattern and a second gate electrode; and a light-emitting device disposed on the pixel area of the device substrate, the light-emitting device electrically connected to the second thin film transistor, wherein the second semiconductor pattern includes a first sub-channel and a second sub-channel disposed side by side between a drain region and a source region, wherein the second gate electrode includes a first sub-gate overlapping the first sub-channel and a second sub-gate overlapping the second sub-channel, and wherein an electric field applied to the first sub-channel by the first sub-gate is different from an electric field applied to the second sub-channel by the second sub-gate electrically connected to the first sub-gate.

The work-function ratio of the first sub-gate and the second sub-gate may be 1.2 or less.

The second sub-channel may be disposed between the drain region and the first sub-channel.

A resistance of the second sub-channel may be a same as a resistance of the first sub-channel.

The gate electrode may include a third sub-gate. The third sub-gate may have a greater work-function than the first sub-gate. The semiconductor pattern may include a third sub-channel overlapping with the third sub-gate. The first sub-channel may be disposed between the second sub-channel and the third sub-channel.

A work-function of the third sub-gate may be a same as a work-function of the second sub-gate.

The first sub-gate and the second sub-gate may include a metal.

The pixel driving circuit and the light-emitting device may be supported by a device substrate. The first sub-gate and the second sub-gate may be disposed between the device substrate and the semiconductor pattern.

In another aspect, there is provided a display apparatus comprising a device substrate. A first thin film transistor, a second thin film transistor and a light-emitting device are disposed on a pixel area of a device substrate. The first thin film transistor includes a first semiconductor pattern and a first gate electrode. The second thin film transistor includes a second semiconductor pattern and a second gate electrode. The light-emitting device is electrically connected to the second thin film transistor. The second semiconductor pattern includes a first sub-channel and a second sub-channel. The first sub-channel and the second sub-channel are disposed side by side between a drain region and a source region. The second gate electrode includes a first sub-gate and a second sub-gate. The first sub-gate overlaps the first sub-channel. The second sub-gate overlaps the second sub-channel. The second sub-gate electrically connected to the first sub-gate. An electric field applied to the first sub-channel by the first sub-gate is different from an electric field applied to the second sub-channel by the second sub-gate.

The first semiconductor pattern and the second semiconductor pattern may include an oxide semiconductor.

A distance between the second sub-channel and the second sub-gate may be a same as a distance between the first sub-channel and the first sub-gate.

The second sub-gate may be in contact with a side surface of the first sub-gate.

The second sub-gate may include a different material from the first sub-gate.

The first gate electrode may include a same material as the first sub-gate.

A length of the second sub-channel may be different from a length of the first sub-channel.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate various aspects of the present disclosure and together with the description serve to explain the principle of the present disclosure.

In the drawings:

FIG. 1 is a view schematically showing a display apparatus according to an aspect of the present disclosure;

FIG. 2 is a view showing a circuit of a pixel area in the display apparatus according to the aspect of the present disclosure;

FIG. 3 is a view showing a cross-section taken along I-I′ of FIG. 1 and a cross-section of the pixel area in the display apparatus according to the aspect of the present disclosure;

FIG. 4 is an enlarged view of K1 region in FIG. 3;

FIG. 5 is a graph showing a change rate in electric field according to the work-function ratio of a first sub-gate and a second sub-gate in the display apparatus according to the aspect of the present disclosure;

FIG. 6 is a graph showing a change rate in driving current according to the work-function ratio of the first sub-gate and the second sub-gate in the display apparatus according to the aspect of the present disclosure; and

FIGS. 7 to 10 are views showing the display apparatus according to another aspect of the present disclosure.

### DETAILED DESCRIPTION

Hereinafter, details related to the above, technical configurations, and operational effects of the aspects of the present disclosure will be clearly understood by the following detailed description with reference to the drawings, which illustrate some aspects of the present disclosure. Here, the aspects of the present disclosure are provided to allow the technical sprit of the present disclosure to be satisfactorily transferred to those skilled in the art, and thus the present disclosure may be embodied in other forms and is not limited to the aspects described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used to describe particular aspects, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

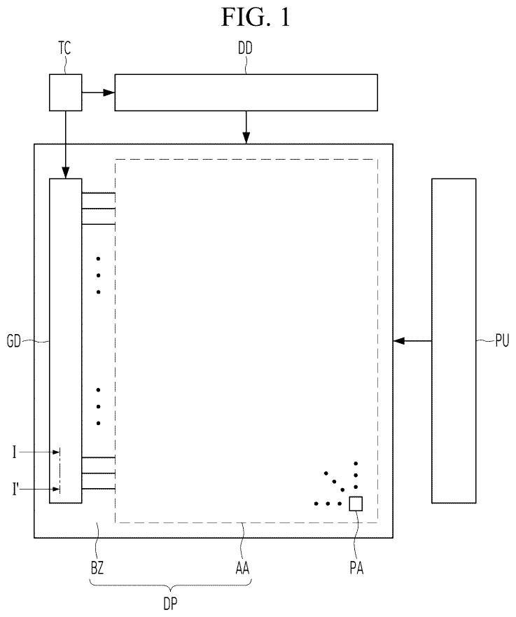

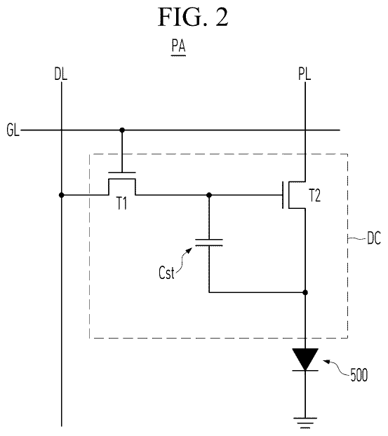

FIG. 1 is a view schematically showing a display apparatus according to an aspect of the present disclosure. FIG. 2 is a view showing a circuit of a pixel area in the display apparatus according to the aspect of the present disclosure.

Referring to FIGS. 1 and 2, the display apparatus according to the aspect of the present disclosure may include a display panel DP. The display panel DP may generate an image provided to a user. For example, the display panel DP may include a plurality of pixel area PA. Various signals may be provided in each pixel area PA through signal wirings GL, DL and PL. For example, the signal wirings GL, DL and PL may include gate lines GL sequentially applying a gate signal to each pixel area PA, data lines DL applying a data signal to each pixel area PA, and power voltage supply lines PL supplying a power voltage to each pixel area PA. The gate lines GL may be electrically connected to a gate driver GD. The data lines DL may be electrically connected to a data driver DD. The gate driver GD and the data driver DD may be controlled by a timing controller TC. For example, the gate driver GD may receive clock signals, reset signals and a start signal from the timing controller TC, and the data driver DD may receive digital video data and a source timing signal from the timing controller TC. The power voltage supply lines PL may be electrically connected to a power unit PU.

The display panel DP may include an active area AA in which the pixel areas PA are disposed, and a bezel area BZ being disposed outside the active area AA. The bezel area BZ may be disposed outside the pixel areas PA. For example, the active area AA may be surrounded by the bezel area BZ. At least one of the gate driver GD, the data driver DD, the timing controller TC and the power unit PU may be disposed on the bezel area BZ of the display panel DP. For example, the display apparatus according to the aspect of the present disclosure may be a GIP (Gate In Panel) type display apparatus in which the gate driver GD is formed on the bezel area BZ of the display panel DP. Each of the signal wiring GL, DL and PL may include a region disposed on the bezel area BZ.

Each of the pixel areas PA may realize a specific color. For example, a light-emitting device 500 and a pixel driving circuit DC electrically connected to the light-emitting device 500 may be disposed in each pixel area PA. The signal wirings GL, DL and PL may be electrically connected to the pixel driving circuit DC of each pixel area PA. For example, the pixel driving circuit DC of each pixel area PA may be electrically connected to one of the gate lines GL, one of the data lines DL, and one of the power voltage supply lines PL. The pixel driving circuit DC of each pixel area PA may supply a driving current corresponding to the data signal to the light-emitting device 500 of the corresponding pixel area PA according to the gate signal for one frame. For example, the pixel driving circuit DC of each pixel area PA may include a first thin film transistor T1, a second thin film transistor T2 and a storage capacitor Cst.

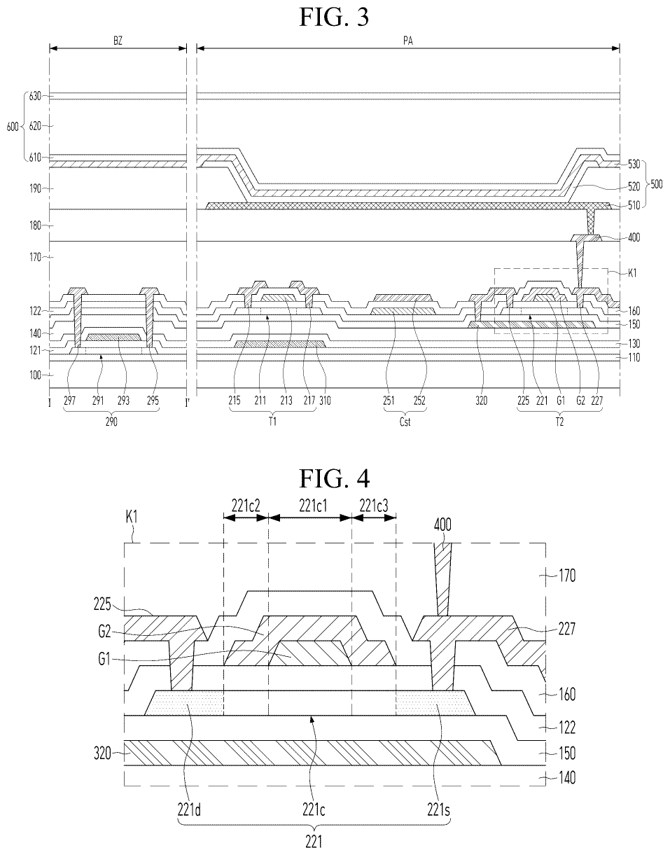

FIG. 3 is a view showing a cross-section taken along I-I′ of FIG. 1 and a cross-section of the pixel area in the display apparatus according to the aspect of the present disclosure. FIG. 4 is an enlarged view of K1 region in FIG. 3.

Referring to FIGS. 2 to 4, the first thin film transistor T1 of each pixel area PA may transmit the data signal to the second thin film transistor T2 of the corresponding pixel area PA according to the gate signal. For example, the first thin film transistor T1 of each pixel area PA may be a switching thin film transistor. The first thin film transistor T1 of each pixel area PA may include a first semiconductor pattern 211, a first gate electrode 213, a first drain electrode 215 and a first source electrode 217. For example, the first gate electrode 213 of each pixel area PA may be electrically connected to the corresponding gate line GL, and the first drain electrode 215 of each pixel area PA may be electrically connected to the corresponding date line DL.

The first semiconductor pattern 211 may include a semiconductor material. For example, the first semiconductor pattern 211 may include an oxide semiconductor, such as IGZO. The first semiconductor pattern 211 may include a first drain region, a first channel region and a first source region. The first channel region may be disposed between the first drain region and the first source region. The first drain region and the first source region may have a smaller resistance than the first channel region. For example, the first drain region and the first source region may include a conductive region of an oxide semiconductor. The first channel region may be a region of an oxide semiconductor, which is not conductorized.

The first gate electrode 213 may be disposed on a portion of the first semiconductor pattern 211. For example, the first gate electrode 213 may overlap the first channel region of the first semiconductor pattern 211. The first drain region and the first source region of the first semiconductor pattern 211 may be disposed outside the first gate electrode 213. The first gate electrode 213 may include a conductive material. For example, the first gate electrode 213 may include a metal, such as aluminum (Al), chrome (Cr), copper (Cu), molybdenum (Mo), titanium (Ti) and tungsten (W). The first gate electrode 213 may be insulated from the first semiconductor pattern 211. For example, the first drain region of the first semiconductor pattern 211 may be electrically connected to the first source region of the first semiconductor pattern 211 according to a voltage applied to the first gate electrode 213.

The first drain electrode 215 may include a conductive material. For example, the first drain electrode 215 may include a metal, such as aluminum (Al), chrome (Cr), copper (Cu), molybdenum (Mo), titanium (Ti) and tungsten (W). The first drain electrode 215 may include a different material from the first gate electrode 213. The first drain electrode 215 may be disposed on a different layer from the first gate electrode 213. For example, the first drain electrode 215 may be insulated from the first gate electrode 213. The first drain electrode 215 may be electrically connected to the first drain region of the first semiconductor pattern 211.

The first source electrode 217 may include a conductive material. For example, the first source electrode 217 may include a metal, such as aluminum (Al), chrome (Cr), copper (Cu), molybdenum (Mo), titanium (Ti) and tungsten (W). The first source electrode 217 may include a different material from the first gate electrode 213. The first source electrode 217 may be disposed on a different layer from the first gate electrode 213. For example, the first source electrode 217 may be insulated from the first gate electrode 213. The first source electrode 217 may be disposed on a same layer as the first drain electrode 215. For example, the first source electrode 217 may include a same material as the first drain electrode 215. The first source electrode 217 may be formed by a same process as the first drain electrode 215. For example, the first source electrode 217 may be formed simultaneously with the first drain electrode 215. The first source electrode 217 may be spaced apart from the first drain electrode 215. The first source electrode 217 may be electrically connected to the first source region of the first semiconductor pattern 211.

The second thin film transistor T2 of each pixel area PA may generate the driving current corresponding to the data signal. For example, the second thin film transistor T2 of each pixel area PA may be a driving thin film transistor. The second thin film transistor T2 of each pixel area PA may include a second semiconductor pattern 221, a second gate electrode 223, a second drain electrode 225 and a second source electrode 227. For example, the second gate electrode 223 of each pixel area PA may be electrically connected to the first source electrode 217 of the corresponding pixel area PA, and the second drain electrode 225 of each pixel area PA may be electrically connected to the corresponding power voltage supply line PL.

The second semiconductor pattern 221 may include a semiconductor material. For example, the second semiconductor pattern 221 may include an oxide semiconductor, such as IGZO. The second semiconductor pattern 221 may include a same material as the first semiconductor pattern 211. The second semiconductor pattern 221 may be disposed on a same layer as the first semiconductor pattern 211. The second semiconductor pattern 221 may be formed by a same process as the first semiconductor pattern 211. For example, second semiconductor pattern 221 may be formed simultaneously with the first semiconductor pattern 211.

The second semiconductor pattern 221 may include a second drain region 221d, a second channel region 221c and a second source region 221s. The second channel region 221c may be disposed between the second drain region 221d and the second source region 221s. The second drain region 221d and the second source region 221s may have a smaller resistance than the second channel region 221c. For example, the second drain region 221d and the second source region 221s may include a conductive region of an oxide semiconductor. The second channel region 221c may be a region of an oxide semiconductor, which is not conductorized.

The second channel region 221 may include a first sub-channel 221c1, a second sub-channel 221c2 and a third sub-channel 221c3, which are parallel to each other between the second drain region 221d and the second source region 221s. The first sub-channel 221c1 may be disposed between the second sub-channel 221c2 and the third sub-channel 221c3. For example, the second sub-channel 221c2 may be disposed between the second drain region 221d and the first sub-channel 221c1, and the third sub-channel 221c3 may be disposed between the first sub-channel 221c1 and the second source region 221s. A resistance of the third sub-channel 221c3 may be a same as a resistance of the second sub-channel 221c2. The second sub-channel 221c2 and the third sub-channel 221c3 may have a same resistance as the first sub-channel 221c1. For example, the amount of oxygen contained in the first sub-channel 221c1 may be a same as the amount of oxygen contained in the second sub-channel 221c2 and the amount of oxygen contained in the third sub-channel 221c3. The amount of oxygen contained in the second drain region 221d and the amount of oxygen contained in the second source region 221s may be smaller than the amount of oxygen contained in the first sub-channel 221c1, the amount of oxygen contained in the second sub-channel 221c2 and the amount of oxygen contained in the third sub-channel 221c3.

The second gate electrode 223 may be disposed on a portion of the second semiconductor pattern 221. For example, the second gate electrode 223 may disposed on the second channel region 221c of the second semiconductor pattern 221. The second drain region 221d and the second source region 221s of the second semiconductor pattern 221 may be disposed outside the second gate electrode 223. The second gate electrode 223 may include a conductive material. For example, the second gate electrode 223 may include a metal, such as aluminum (Al), chrome (Cr), copper (Cu), molybdenum (Mo), titanium (Ti) and tungsten (W). The second gate electrode 223 may be insulated from the second semiconductor pattern 221. For example, the second drain region 221d of the second semiconductor pattern 221 may be electrically connected to the second source region 221s of the second semiconductor pattern 221 according to a voltage applied to the second gate electrode 223.

The second gate electrode 223 may include a first sub-gate G1 and a second sub-gate G2. The first sub-gate G1 may overlap the first sub-channel 221c1. The second sub-gate G2 may overlap the first sub-channel 221c1, the second sub-channel 221c2 and the third sub-channel 221c3. For example, the first sub-gate G1 may be disposed between the first sub-channel 221c1 and the second sub-gate G2. The second sub-channel 221c2 and the third sub-channel 221c3 may be disposed outside the first sub-gate G1. For example, a channel by the first sub-gate G1 may be formed in the first sub-channel 221c1, and a channel by the second sub-gate G2 may be formed in the second sub-channel 221c2 and the third sub-channel 221c3. The second sub-gate G2 may be electrically connected to the first sub-gate G1. A distance between the second sub-channel 221c2 and the second sub-gate G2 and a distance between the third sub-channel 221c3 and the second sub-gate G2 may be a same as a distance between the first sub-channel 221c1 and the first sub-gate G1. For example, a lower surface of the first sub-gate G1 toward the second semiconductor pattern 221 may have a same level as a lower surface of the second sub-gate G2 toward the second semiconductor pattern 221 on the second sub-channel 221c2 and the third sub-channel 221c3. The first sub-gate G1 may be covered by the second sub-gate G2. A side surface and an upper surface of the first sub-gate G1, which are disposed toward the second sub-gate G2 may be in direct contact with the second sub-gate G2.

The first sub-gate G1 and the second sub-gate G2 may a metal. The second sub-gate G2 may include a different material from the first sub-gate G1. For example, a work-function of the second sub-gate G2 may be different from a work-function of the first sub-gate G1. In a general thin film transistor, an electric field applied to a channel of a semiconductor pattern by a gate electrode may be inversely proportional to the work-function of the corresponding gate electrode. For example, an electric field applied to the second sub-channel 221c2 and an electric field applied to the third sub-channel 221c3 by the second sub-gate G2 may be different from an electric field applied to the first sub-channel 221c1 by the first sub-gate G1.

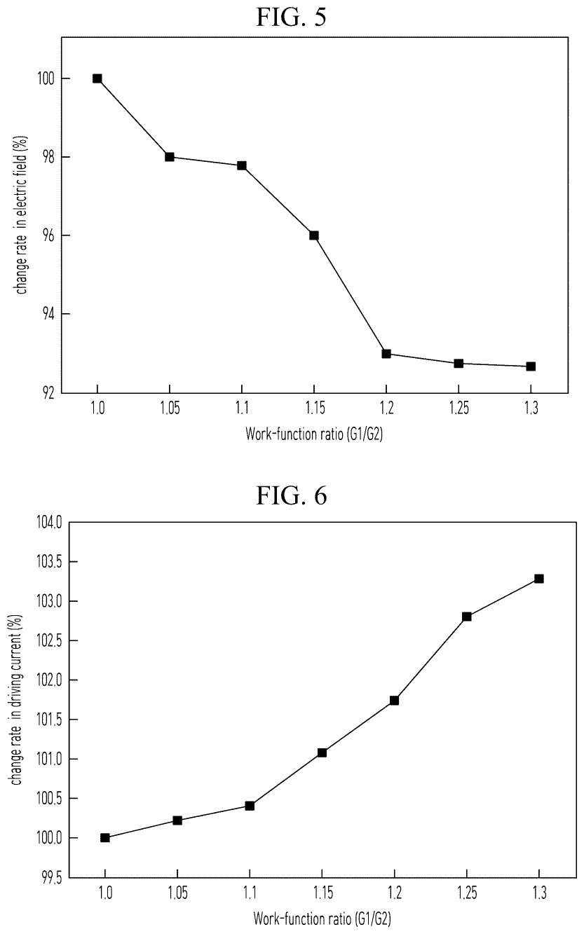

FIG. 5 is a graph showing a change rate in the electric field according to the work-function ratio of a first sub-gate G1 and a second sub-gate G2 in the display apparatus according to the aspect of the present disclosure. FIG. 6 is a graph showing a change rate in the driving current according to the work-function ratio of the first sub-gate G1 and the second sub-gate G2 in the display apparatus according to the aspect of the present disclosure.

Referring to FIGS. 5 and 6, in the display apparatus according to the aspect of the present disclosure, the work-function ratio G1/G2 of the first sub-gate G1 and the second sub-gate G2 may be inversely proportional to the electric field applied to the second channel region 221c of the second semiconductor pattern 221, and the driving current generated by the second thin film transistor T2 may be proportional to the work-function ratio G1/G2 of the first sub-gate G1 and the second sub-gate G2. For example, when the second sub-gate G2 has a larger work-function than the first sub-gate G1, the electric field applied to the second sub-channel 221c2 and the third sub-channel 221c3 by the second sub-gate G2 may be smaller than the electric field applied to the first sub-channel 221c1 by the first sub-gate G1. When the electric field applied to the second sub-channel 221c2 and the third sub-channel 221c3 are reduced, the driving current generated by the second thin film transistor T2 may be increased. That is, in the display apparatus according to the aspect of the present disclosure, the driving current generated by the second thin film transistor T2 of each pixel area PA may be increased, without reducing a length of the second channel region 221c in each pixel area PA. Thus, in the display apparatus according to the aspect of the present disclosure, occurrence of leakage current in the second semiconductor pattern 221 of each pixel area PA may be malfunction of the second thin film transistor T2 in each pixel area PA may be prevented, and the electrical characteristics of the second thin film transistor T2 in each pixel area PA may be improved. Therefore, in the display apparatus according to the aspect of the present disclosure, efficiency and reliability of the pixel driving circuit DC in each pixel area PA may be improved.

Referring to FIGS. 2 to 4, the first sub-channel 221c1 may be disposed between the second sub-channel 221c2 and the third sub-channel 221c3. For example, the second sub-channel 221c2 may be disposed between the second drain region 221d and the first sub-channel 221c1, and the third sub-channel 221c3 may be disposed between the first sub-channel 221c1 and the second source region 221s. In general, speed and energy of electrons moving through a channel formed in a semiconductor pattern are proportional to an electric field applied to the corresponding channel. Thus, in the display apparatus according to the aspect of the present disclosure, speed and energy of electrons moving through a channel formed in the second channel region 221c may be reduced due to the second sub-channel 221c2 and the third sub-channel 221c3. That is, in the display apparatus according to the aspect of the present disclosure, the second sub-channel 221c2 and the third sub-channel 221c3 may be function as a lightly doped drain (LDD). Therefore, in the display apparatus according to the aspect of the present disclosure, the malfunction of the second thin film transistor T2 in each pixel area PA may be prevented, without doping process. And, in the display apparatus according to the aspect of the present disclosure, reliability of the pixel driving circuit DC in each pixel area PA may be improved.

The first sub-gate G1 may be disposed on a same layer as the first gate electrode 213. The first sub-gate G1 may include a same material as the first gate electrode 213. The first sub-gate G1 may be formed by a same process as the first gate electrode 213. For example, the first sub-gate G1 may be formed simultaneously with the first gate electrode 213. The second sub-gate G2 may include a different material from the first gate electrode 213. For example, a work-function of the second sub-gate G2 may be larger than a work-function of the first gate electrode 213. A process of forming the second sub-gate G2 may be performed after the formation of the first gate electrode 213 and the first sub-gate G1.

The second drain electrode 225 may include a conductive material. For example, the second drain electrode 225 may include a metal, such as aluminum (Al), chrome (Cr), copper (Cu), molybdenum (Mo), titanium (Ti) and tungsten (W). The second drain electrode 225 may include a different material from the first sub-gate G1 and the second sub-gate G2. The second drain electrode 225 may be disposed on a different layer from the first sub-gate G1 and the second sub-gate G2. For example, the second drain electrode 225 may be insulated from the second gate electrode 223. The second drain electrode 225 may be disposed on a same layer as the first drain electrode 215. The second drain electrode 225 may include a same material as the first drain electrode 215. The second drain electrode 225 may be formed by a same process as the first drain electrode 215. For example, the second drain electrode 225 may be formed simultaneously with the first drain electrode 215. The second drain electrode 225 may be electrically connected to the second drain region 221d of the second semiconductor pattern 221.

The second source electrode 227 may include a conductive material. For example, the second source electrode 227 may include a metal, such as aluminum (Al), chrome (Cr), copper (Cu), molybdenum (Mo), titanium (Ti) and tungsten (W). The second source electrode 227 may include a different material from the first sub-gate G1 and the second sub-gate G2. The second source electrode 227 may be disposed on a different layer from the first sub-gate G1 and the second sub-gate G2. For example, the second source electrode 227 may be insulated from the second gate electrode 223. The second source electrode 227 may be disposed on a same layer as the second drain electrode 225. The second source electrode 227 may include a same material as the second drain electrode 225. The second source electrode 227 may be formed by a same process as the second drain electrode 225. For example, the second source electrode 227 may be formed simultaneously with the second drain electrode 225. The second source electrode 227 may be spaced apart from the second drain electrode 225. The second source electrode 227 may be electrically connected to the second source region 221s of the second semiconductor pattern 221.

The storage capacitor Cst of each pixel area PA may maintain a voltage applied to the second gate electrode 223 of the corresponding pixel area PA for one frame. For example, the storage capacitor Cst of each pixel area PA may be electrically connected between the second gate electrode 223 and the second source electrode 227 of the corresponding pixel area PA. The storage capacitor Cst of each pixel area PA may have a stacked structure of capacitor electrodes 251 and 252. The storage capacitor Cst of each pixel area PA may be formed by using a process of forming the first thin film transistor T1 and the second thin film transistor T2 of the corresponding pixel area PA. For example, the storage capacitor Cst of each pixel area PA may include a first capacitor electrode 251 disposed on a same layer as the first sub-gate G1 and a second capacitor electrode 252 disposed on a same layer as the second source electrode 227. Thus, in the display apparatus according to the aspect of the present disclosure, a process of forming the pixel driving circuit DC in each pixel area PA may be simplified. Therefore, in the display apparatus according to the aspect of the present disclosure, process efficiency may be improved.

The gate driver GD formed on the bezel area BZ may include at least one circuit thin film transistor 290. The circuit thin film transistor 290 may be a switching thin film transistor. For example, the circuit thin film transistor 290 may include a circuit semiconductor pattern 291, a circuit gate electrode 293, a circuit drain electrode 295 and a circuit source electrode 297.

The circuit semiconductor pattern 291 may include a semiconductor material. The circuit semiconductor pattern 291 may be disposed on a different layer from the first semiconductor pattern 211 and the second semiconductor pattern 221 of each pixel area PA. The circuit semiconductor pattern 291 may include a material different from the first semiconductor pattern 211 and the second semiconductor pattern 221 of each pixel area PA. For example, the circuit semiconductor pattern 291 may include low-temperature poly-Si (LTPS). The circuit semiconductor pattern 291 may include a circuit drain region, a circuit channel region, and a circuit source region. The circuit channel region may be disposed between the circuit drain region and the circuit source region. The circuit drain region and the circuit source region may have a smaller resistance than the circuit channel region. For example, the circuit drain region and the circuit source region may include conductive impurities. The circuit channel region may be a region, which is not doped with conductive impurities.

The circuit gate electrode 293 may be disposed on a portion of the circuit semiconductor pattern 291. For example, the circuit gate electrode 293 may overlap the circuit channel region of the circuit semiconductor pattern 291. The circuit drain region and the circuit source region of the circuit semiconductor pattern 291 may be disposed outside the circuit gate electrode 293. The circuit gate electrode 293 may include a conductive material. For example, the circuit gate electrode 293 may include a metal, such as aluminum (Al), chrome (Cr), copper (Cu), molybdenum (Mo), titanium (Ti) and tungsten (W). The circuit gate electrode 293 may be insulated from the circuit semiconductor pattern 291. For example, the circuit drain region of the circuit semiconductor pattern 291 may be electrically connected to the circuit source region of the circuit semiconductor pattern 291 according to a voltage applied to the circuit gate electrode 293.

The circuit gate electrode 293 may be disposed on a different layer from the first gate electrode 213, the first sub-gate G1 and the second sub-gate G2 of each pixel area PA. For example, the circuit gate electrode 293 may include a different material from the first gate electrode 213, the first sub-gate G1 and the second sub-gate G2 of each pixel area PA.

The circuit drain electrode 295 may include a conductive material. For example, the circuit drain electrode 295 may include a metal, such as aluminum (Al), chrome (Cr), copper (Cu), molybdenum (Mo), titanium (Ti) and tungsten (W). The circuit drain electrode 295 may include a different material from the circuit gate electrode 293. The circuit drain electrode 295 may be disposed on a different layer from the circuit gate electrode 293. For example, the circuit drain electrode 295 may be insulated from the circuit gate electrode 293. The circuit drain electrode 295 may be disposed on a same layer as the first drain electrode 215 of each pixel area PA. The circuit drain electrode 295 may include a same material as the first drain electrode 215 of each pixel area PA. The circuit drain electrode 295 may be formed by a same process as the first drain electrode 215 of each pixel area PA. For example, the circuit drain electrode 295 may be formed simultaneously with the first drain electrode 215 of each pixel area PA. The circuit drain electrode 295 may be electrically connected to the circuit drain region of the circuit semiconductor pattern 291.

The circuit source electrode 297 may include a conductive material. For example, the circuit source electrode 297 may include a metal such as aluminum (Al), chrome (Cr), copper (Cu), molybdenum (Mo), titanium (Ti) and tungsten (W). The circuit source electrode 297 may include a different material from the circuit gate electrode 293. The circuit source electrode 297 may be disposed on a different layer from the circuit gate electrode 293. For example, the circuit source electrode 297 may be insulated from the circuit gate electrode 293. The circuit source electrode 297 may be disposed on a same layer as the circuit drain electrode 295. The circuit source electrode 297 may include a same material as the circuit drain electrode 295. The circuit source electrode 297 may be formed by a same process as the circuit drain electrode 295. For example, the circuit source electrode 297 may be formed simultaneously with the circuit drain electrode 295. The circuit source electrode 297 may be spaced apart from the circuit drain electrode 295. The circuit source electrode 297 may be electrically connected to the circuit source region of the circuit semiconductor pattern 291.

The pixel driving circuit DC of each pixel area PA and the circuit thin film transistor 290 may be disposed on a device substrate 100. For example, the light-emitting device 500 and the pixel driving circuit DC of each pixel area PA and the circuit thin film transistor 290 may be supported by the device substrate 100. The device substrate 100 may include an insulating material. For example, the device substrate 100 may include glass or plastic. A plurality of insulating layers 110, 121, 122, 130, 140, 150, 160, 170, 180 and 190 for preventing unnecessary electrical connection in each pixel area PA and the gate driver GD may be disposed on the device substrate 100. For example, a lower buffer layer 110, a first gate insulating layer 121, a second gate insulating layer 122, a lower interlayer insulating layer 130, a separation insulating layer 140, an upper buffer layer 150, an upper interlayer insulating layer 160, a lower planarization layer 170, an upper planarization layer 180 and a bank insulating layer 190 may be disposed on the device substrate 100.

The lower buffer layer 110 may be disposed close to the device substrate 100. The lower buffer layer 110 may prevent pollution due to the device substrate 100 in a process of forming the pixel driving circuit DC of each pixel area PA and the circuit thin film transistor 290. For example, an upper surface of the device substrate 100 toward the pixel driving circuit DC of each pixel area PA and the circuit thin film transistor 290 may be completely covered by the lower buffer layer 110. The lower buffer layer 110 may be in direct contact with the upper surface of the device substrate 100. The pixel driving circuit DC of each pixel area PA and the circuit thin film transistor 290 may be disposed on the lower buffer layer 110. The lower buffer layer 110 may include an insulating material. For example, the lower buffer layer 110 may include an inorganic insulating material, such as silicon oxide (SiOx) and silicon nitride (SiNx).

The first gate insulating layer 121 may be disposed on the lower buffer layer 110. The circuit gate electrode 293 may be insulated from the circuit semiconductor pattern 291 by the first gate insulating layer 121. For example, the circuit semiconductor pattern 291 may be covered by the first gate insulating layer 121. The circuit gate electrode 293 may be disposed on the first gate insulating layer 121. The first gate insulating layer 121 may include an insulating material. For example, the first gate insulating layer 121 may include an inorganic insulating material, such as silicon oxide (SiOx) and silicon nitride (SiNx).

The lower interlayer insulating layer 130 may be disposed on the first gate insulating layer 121. The circuit drain electrode 295 and the circuit source electrode 297 may be insulated from the circuit gate electrode 293 by the lower interlayer insulating layer 130. For example, the circuit gate electrode 293 may be covered by the lower interlayer insulating layer 130. The circuit drain electrode 295 and the circuit source electrode 297 may be disposed on the lower interlayer insulating layer 130. The lower interlayer insulating layer 130 may include an insulating material. For example, the lower interlayer insulating layer 130 may include an inorganic insulating material, such as silicon oxide (SiOx) and silicon nitride (SiNx).

A first light-blocking pattern 310 may be disposed between the first gate insulating layer 121 and the lower interlayer insulating layer 130 of each pixel area PA. The first light-blocking pattern 310 of each pixel area PA may include a material absorbing or reflecting light. For example, the first light-blocking pattern 310 of each pixel area PA may include a metal. The first light-blocking pattern 310 of each pixel area PA may be disposed on a same layer as the circuit gate electrode 293. The first light-blocking pattern 310 of each pixel area PA may include a same material as the circuit gate electrode 293. The first light-blocking pattern 310 of each pixel area PA may be formed by a same process as the circuit gate electrode 293. For example, the first light-blocking pattern 310 of each pixel area PA may be formed simultaneously with the circuit gate electrode 293. The first light-blocking pattern 310 of each pixel area PA may overlap the first semiconductor pattern 211 of the corresponding pixel area PA. For example, light traveling toward the first semiconductor pattern 211 of each pixel area PA through the device substrate 100 may be blocked by the first light-blocking pattern 310 of the corresponding pixel area PA. Thus, in the display apparatus according to the aspect of the present disclosure, difference in characteristics of the first thin film transistor T1 in each pixel area PA due to external light may be prevented, without decreasing process efficiency.

A specific voltage may be applied to the first light-blocking pattern 310 of each pixel area PA. For example, the first light-blocking pattern 310 of each pixel area PA may be electrically connected to the first gate electrode 213 of the corresponding pixel area PA. Thus, in the display apparatus according to the aspect of the present disclosure, the first light-blocking pattern 310 of each pixel area PA may function as a gate electrode of the first thin film transistor T1 in the corresponding pixel area PA. Therefore, in the display apparatus according to the aspect of the present disclosure, response speed of the first thin film transistor T1 in each pixel area PA may be increased.

The separation insulating layer 140 may be disposed on the lower interlayer insulating layer 130. The separation insulating layer 140 may prevent the deterioration and the damage of the circuit semiconductor pattern 291 due to a process of forming the pixel driving circuit DC in each pixel area PA. For example, the first thin film transistor T1, the second thin film transistor T2 and the storage capacitor Cst of each pixel area PA may be disposed on the separation insulating layer 140. The separation insulating layer 140 may include an insulating material. For example, the separation insulating layer 140 may include an inorganic insulating material, such as silicon oxide (SiOx) and silicon nitride (SiNx). The separation insulating layer 140 may be thicker than the lower interlayer insulating layer 130. The separation insulating layer 140 may have a multi-layer structure. For example, the separation insulating layer 140 may have a stacked structure of an inorganic insulating layer made of silicon oxide (SiOx) and an inorganic insulating layer made of silicon nitride (SiNx).

The upper buffer layer 150 may be disposed on the separation insulating layer 140. The upper buffer layer 150 may prevent pollution due to the first light-blocking pattern 310 of each pixel area PA, the circuit semiconductor pattern 291 and the circuit gate electrode 293 in a process of forming the first semiconductor pattern 211 and the second semiconductor pattern 221 of each pixel area PA. For example, the first semiconductor pattern 211 and the second semiconductor pattern 221 of each pixel area PA may be disposed on the upper buffer layer 150. The upper buffer layer 150 may include an insulating material. For example, the upper buffer layer 150 may include an inorganic insulating material, such as silicon oxide (SiOx) and silicon nitride (SiNx).

A second light-blocking pattern 320 may be disposed between the separation insulating layer 140 and the upper buffer layer 150 of each pixel area PA. The second light-blocking pattern 320 of each pixel area PA may include a material absorbing or reflecting light. For example, the second light-blocking pattern 320 of each pixel area PA may include a metal. The second light-blocking pattern 320 of each pixel area PA may overlap the second semiconductor pattern 221 of the corresponding pixel area PA. For example, light traveling toward the second semiconductor pattern 221 of each pixel area PA through the device substrate 100 may be blocked by the second light-blocking pattern 320 of the corresponding pixel area PA. Thus, in the display apparatus according to the aspect of the present disclosure, difference in characteristics of the second thin film transistor T2 in each pixel area PA due to the external light may be prevented.

A specific voltage may be applied to the second light-blocking pattern 320 of each pixel area PA. For example, the second light-blocking pattern 320 of each pixel area PA may be electrically connected to the second drain electrode 225 of the corresponding pixel area PA. Thus, in the display apparatus according to the aspect of the present disclosure, difference in characteristics of the second thin film transistor T2 in each pixel area PA due to the external light may be effectively prevented.

A distance between the second light-blocking pattern 320 and the second semiconductor pattern 221 in each pixel area PA may be smaller than a distance between the first light-blocking pattern 310 and the first semiconductor pattern 211 in the corresponding pixel area PA. Generally, the amount of change in the effective gate voltage of a thin film transistor disposed on a conductive pattern may be determined by the following equation. Here, ΔV_{eff} represents the amount of change in the effective gate voltage, ΔV_{GAT} represents the amount of change in a voltage applied to the gate electrode, C1 represents capacitance of the parasitic capacitor formed between the conductive pattern and a semiconductor pattern of the corresponding thin film transistor, C2 represents capacitance of the parasitic capacitor formed between the semiconductor pattern and the gate electrode of the corresponding thin film transistor, and C_{ACT} represents capacitance of the parasitic capacitor formed by a voltage applied to a drain region and a source region of the corresponding thin film transistor.

$$Δ {V}_{eff} = \frac{C 2}{C 2 + {C}_{ACT} + C 1} \times Δ {V}_{GAT} \qquad [ Equation 1 ]$$

Capacitance of a capacitor is inversely proportional to a distance between conductors constituting the corresponding capacitor. In the display apparatus according to the aspect of the present disclosure, the capacitance of the parasitic capacitor formed between the second light-blocking pattern 320 and the second semiconductor pattern 221 of each pixel area PA may be larger than the capacitance of the parasitic capacitor formed between the first light-blocking pattern 310 and the first semiconductor pattern 211 of the corresponding pixel area PA. Thus, in the display apparatus according to the aspect of the present disclosure, the amount of change in the effective gate voltage of the second thin film transistor T2 in each pixel area PA may be smaller than the amount of change in the effective gate voltage of the first thin film transistor T1 in the corresponding pixel area PA. In a general thin film transistor, when the amount of change in the effective gate voltage is reduced, the amount of change in a current according to change in a voltage applied to the gate electrode of the corresponding thin film transistor may be decreased, and an S-factor of the corresponding thin film transistor may be increased. Here, the S-factor of the thin film transistor means an inverse ratio of the amount of change in the current generated by the corresponding thin film transistor and the amount of change in the voltage applied to the gate electrode of the corresponding thin film transistor. That is, in the display apparatus according to the aspect of the present disclosure, the S-factor of the second thin film transistor T2 in each pixel area PA may have a larger value than the S-factor of the first thin film transistor T1 in the corresponding pixel area PA, and the amount of change in the driving current generated by each pixel area PA according to change in the voltage applied to the second gate electrode 223 of the corresponding pixel area PA may be reduced. Therefore, in the display apparatus according to the aspect of the present disclosure, occurrence of stains due may be prevented, when a low gray-scale image is realized.

The second gate insulating layer 122 may be disposed on the upper buffer layer 150. The first gate electrode 213 and the second gate electrode 223 of each pixel area PA may be insulated from the first semiconductor pattern 211 and the second semiconductor pattern 221 of the corresponding pixel area PA by the second gate insulating layer 122. For example, the first semiconductor pattern 211 and the second semiconductor pattern 221 of each pixel area PA may be covered by the second gate insulating layer 122. The first sub-gate G1 of each pixel area PA may be disposed between the second gate insulating layer 122 and the second sub-gate G2 of the corresponding pixel area PA. The second gate insulating layer 122 may include an insulating material. For example, the second gate insulating layer 122 may include an inorganic insulating material, such as silicon oxide (SiOx) and silicon nitride (SiNx).

The upper interlayer insulating layer 160 may be disposed on the second gate insulating layer 122. The first drain electrode 215, the first source electrode 217, the second drain electrode 225 and the second source electrode 227 of each pixel area PA may be insulated from the first gate electrode 213 and the second gate electrode 223 of the corresponding pixel area PA by the upper interlayer insulating layer 160. For example, first gate electrode 213 and the second gate electrode 223 of each pixel area PA may be covered by the upper interlayer insulating layer 160. The second sub-gate G2 of each pixel area PA may be disposed between the first sub-gate G1 of the corresponding pixel area PA and the upper interlayer insulating layer 160. The first drain electrode 215, the first source electrode 217, the second drain electrode 225 and the second source electrode 227 of each pixel area PA may be disposed on the upper interlayer insulating layer 160. The upper interlayer insulating layer 160 may include an insulating material. For example, the upper interlayer insulating layer 160 may include an inorganic insulating material, such as silicon oxide (SiOx) and silicon nitride (SiNx).

The first drain electrode 215 of each pixel area PA may be electrically connected to the first drain region of the first semiconductor pattern 211 in the corresponding pixel area PA passing through the second gate insulating layer 122 and the upper interlayer insulating layer 160 of the corresponding pixel area PA, and the first second electrode 217 of each pixel area PA may be electrically connected to the first source region of the first semiconductor pattern 211 in the corresponding pixel area PA passing through the second gate insulating layer 122 and the upper interlayer insulating layer 160 of the corresponding pixel area PA. The second drain electrode 225 of each pixel area PA may be electrically connected to the second drain region 221d of the second semiconductor pattern 221 in the corresponding pixel area PA passing through the second gate insulating layer 122 and the upper interlayer insulating layer 160 of the corresponding pixel area PA, and the second source electrode 227 of each pixel area PA may be electrically connected to the second source region 221s of the second semiconductor pattern 221 in the corresponding pixel area PA passing through the second gate insulating layer 122 and the upper interlayer insulating layer 160 of the corresponding pixel area PA. A contact hole to connection between the first drain electrode 215 and the first drain region and a contact hole to connection between the first source electrode 217 and the first source region in each pixel area PA may be formed simultaneously with a contact hole to connection between the second drain electrode 225 and the second drain region 221d and a contact hole to connection between the second source electrode 227 and the second source region 221s in each pixel area PA. Thus, in the display apparatus according to the aspect of the present disclosure, process efficiency may be improved.

The second drain electrode 255 of each pixel area PA may be connected to the second light-blocking pattern 320 of the corresponding pixel area PA by penetrating the upper buffer layer 150, the second gate insulating layer 122 and the upper interlayer insulating layer 160. The circuit drain electrode 295 may be connected to the circuit drain region of the circuit semiconductor pattern 291 by penetrating the first gate insulating layer 121, the lower interlayer insulating layer 130, the separation insulating layer 140, the upper buffer layer 150, the second gate insulating layer 122 and the upper interlayer insulating layer 160, and the circuit source electrode 297 may be connected to the circuit source region of the circuit semiconductor pattern 291 by penetrating the first gate insulating layer 121, the lower interlayer insulating layer 130, the separation insulating layer 140, the upper buffer layer 150, the second gate insulating layer 122 and the upper interlayer insulating layer 160. A contact hole to connection between the circuit drain electrode 295 and the circuit drain region and a contact hole to connection between the circuit source electrode 297 and the circuit source region may be formed by using a process of forming a contact hole to connection between the second drain electrode 225 and the second light-blocking pattern 320 of each pixel area PA. For example, the circuit drain electrode 295 and the circuit source electrode 297 may penetrate the upper buffer layer 150, the second gate insulating layer 122 and the upper interlayer insulating layer 160 by holes formed simultaneously with the contact hole to connection between the second drain electrode 255 and the second light-blocking pattern 320 of each pixel area PA.

The lower planarization layer 170 may be disposed on the upper interlayer insulating layer 160. The upper planarization layer 180 may be disposed on the lower planarization layer 170. The lower planarization layer 170 and the upper planarization layer 180 may remove a thickness difference due to the pixel driving circuit DC of each pixel area PA. For example, the first drain electrode 215, the first source electrode 217, the second drain electrode 225, the second source electrode 227 and the second capacitor electrode 252 of each pixel area PA may be covered by the lower planarization layer 170. The lower planarization layer 170 and the upper planarization layer 180 may extend onto the bezel area BZ of the device substrate 100. For example, the lower planarization layer 170 and the upper planarization layer 180 may be stacked on the circuit drain electrode 295 and the circuit source electrode 297. A thickness difference due to the circuit thin film transistor 290 may be removed by the lower planarization layer 170 and the upper planarization layer 180. An upper surface of the upper planarization layer 180 opposite to the device substrate 100 may be a flat surface.

The lower planarization layer 170 and the upper planarization layer 180 may include an insulating material. The lower planarization layer 170 and the upper planarization layer 180 may include a different material from the upper interlayer insulating layer 160. The lower planarization layer 170 and the upper planarization layer 180 may have a material having a relative high fluidity. For example, the lower planarization layer 170 and the upper planarization layer 180 may include an organic insulating material. The upper planarization layer 180 may include a same material as the lower planarization layer 170. For example, an interface between the lower planarization layer 170 and the upper planarization layer 180 may not be recognized.

The light-emitting device 500 of each pixel area PA may be disposed on the upper planarization layer 180 of the corresponding pixel area PA. The light-emitting device 500 of each pixel area PA may emit light displaying a specific color. For example, the light-emitting device 500 of each pixel area PA may include a first electrode 510, a light-emitting unit 520 and a second electrode 530, which are sequentially stacked on the upper planarization layer 180 of the corresponding pixel area PA.

The first electrode 510 may include a conductive material. The first electrode 510 may include a material having a high reflectance. For example, the first electrode 510 may include a metal, such as aluminum (Al) or silver (Ag). The first electrode 510 may have a multi-layer structure. For example, the first electrode 510 may have a structure in which a reflective electrode made of a metal is disposed between transparent electrodes made of a transparent conductive material, such as ITO and IZO.

The light-emitting unit 520 may generate light having luminance corresponding to a voltage difference between the first electrode 510 and the second electrode 530. For example, the light-emitting unit 520 may include at least one emission material layer (EML). The emission material layer may include an emission material. The emission material may include an organic material, an inorganic material, or a hybrid material. For example, the display apparatus according to the aspect of the present disclosure may be an organic light-emitting display apparatus including an organic emission material.

The light-emitting unit 520 may include at least one functional layer to smooth supply holes or electrons. For example, the light-emitting unit 520 may include at least one of a hole injection layer (HIL), a hole transport layer (HTL), an electron transport layer (ETL) and an electron injection layer (EIL). Thus, in the display apparatus according to the aspect of the present disclosure, efficiency of the light-emitting unit 520 may be improved.

The second electrode 530 may include a conductive material. The second electrode 530 may include a different material from the first electrode 510. A transmittance of the second electrode 530 may be greater than a transmittance of the first electrode 510. For example, the second electrode 530 may be a transparent electrode made of a transparent conductive material, such as ITO and IZO, or a translucent electrode in which metals such as Ag and Mg are thinly formed. Thus, in the display apparatus according to the aspect of the present disclosure, light generated by the light-emitting unit 520 may be emitted outside through the second electrode 530.

The light-emitting device 500 of each pixel area PA may be electrically connected to the second thin film transistor T2 of the corresponding pixel area PA. For example, the first electrode 510 of each pixel area PA may be electrically connected to the second source electrode 227 of the corresponding pixel area PA. The first electrode 510 of each pixel area PA may include a region directly contacting the upper surface of the upper planarization layer 180 on the corresponding pixel area PA. The light-emitting unit 520 and the second electrode 530 of each pixel area PA may be stacked on a region of the corresponding first electrode 510 directly contacting the upper surface of the upper planarization layer 180. Thus, in the display apparatus according to the aspect of the present disclosure, luminance deviation according to the generating location of the light emitted from the light-emitting device 500 of each pixel area PA may be prevented.

An intermediate electrode 400 electrically connecting the first electrode 510 of each pixel area PA to the second source electrode 227 of the corresponding pixel area PA may be disposed between the lower planarization layer 170 and the upper planarization layer 180 of the corresponding pixel area PA. The intermediate electrode 400 of each pixel area PA may include a conductive material. The intermediate electrode 400 of each pixel area PA may include a material having a relatively small resistance. For example, the intermediate electrodes 400 may include a metal. The intermediate electrode 400 of each pixel area PA may be in direct contact with the second source electrode 227 and the first electrode 510 of the corresponding pixel area PA. For example, the intermediate electrode 400 of each pixel area PA may be connected to the second source electrode 227 of the corresponding pixel area PA by penetrating the lower planarization layer 170, and the first electrode 510 of each pixel area PA may be connected to the intermediate electrode 400 of the corresponding pixel area PA by penetrating the upper planarization layer 180. Thus, in the display apparatus according to the aspect of the present disclosure, the first electrode 510 of each pixel area PA may be stably connected to the second source electrode 227 of the corresponding pixel area PA. Therefore, in the display apparatus according to the aspect of the present disclosure, reliability for the electrical connection between the pixel driving circuit DC and the light-emitting device 500 in each pixel area PA may be improved.

The bank insulating layer 190 may be disposed on the upper planarization layer 180. The bank insulating layer 190 may define an emission area in each pixel area PA. For example, the bank insulating layer 190 may partially expose the first electrode 510 of each pixel area PA. A portion of each first electrode 510 exposed by the bank insulating layer 190 may be a region directly contacting the upper surface of the upper planarization layer 180. For example, the light-emitting unit 520 and the second electrode 530 of each pixel area PA may be stacked on a portion of the corresponding first electrode 510 exposed by the bank insulating layer 190. An edge of the first electrode 510 in each pixel area PA may be covered by the bank insulating layer 190. For example, the first electrode 510 of each pixel area PA may be insulated from the first electrode 510 of adjacent pixel area PA by the bank insulating layer 190. The bank insulating layer 190 may include an insulating material. For example, the bank insulating layer 190 may include an organic insulating material. The bank insulating layer 190 may include a different material from the upper planarization layer 180.

The light emitted from the light-emitting device 500 of each pixel area PA may display a different color from the light emitted from the light-emitting device 500 of adjacent pixel area PA. For example, the light-emitting unit 520 of each pixel area PA may be spaced apart from the light-emitting unit 520 of adjacent pixel area PA. The light-emitting layer 520 of each pixel area PA may include an end on the bank insulating layer 190.

A voltage applied to the second electrode 530 of each pixel area PA may be a same as a voltage applied to the second electrode 530 of adjacent pixel area PA. For example, the second electrode 530 of each pixel area PA may be electrically connected to the second electrode 530 of adjacent pixel area PA. The second electrode 530 of each pixel area PA may include a same material as the second electrode 530 of adjacent pixel area PA. The second electrode 530 of each pixel area PA may be formed by a same process as the second electrode 530 of adjacent pixel area PA. For example, the second electrode 530 of each pixel area PA may be formed simultaneously with the second electrode 530 of adjacent pixel area PA. The second electrode 530 of each pixel area PA may be in direct contact with the second electrode 530 of adjacent pixel area PA. For example, the second electrode 530 of each pixel area PA may extend on the bank insulating layer 160. Thus, in the display apparatus according to the aspect of the present disclosure, a process of forming the second electrode 530 in each pixel area PA may be simplified. And, in the display apparatus according to the aspect of the present disclosure, the luminance of the light generated by the light-emitting device 500 in each pixel area PA may be adjusted by the data signal applied to the pixel driving circuit DC in the corresponding pixel area PA.

An encapsulation unit 600 may be disposed on the light-emitting device 500 of each pixel area PA. The encapsulation unit 600 may prevent damage of the light-emitting devices 500 due to external moisture and impact. The encapsulation unit 600 may have a multi-layer structure. For example, the encapsulation unit 600 may include a first encapsulating layer 610, a second encapsulating layer 620 and a third encapsulating layer 630, which are sequentially stacked. The first encapsulating layer 610, the second encapsulating layer 620 and the third encapsulating layer 630 may include an insulating material. The second encapsulating layer 620 may include a different material from the first encapsulating layer 610 and the third encapsulating layer 630. For example, the first encapsulating layer 610 and the third encapsulating layer 630 may include an inorganic insulating material, such as silicon oxide (SiOx) and silicon nitride (SiNx), and the second encapsulating layer 620 may include an organic insulating material. A thickness difference due to the light-emitting device 500 of each pixel area PA may be removed by the second encapsulating layer 620. For example, an upper surface of the encapsulation unit 600 opposite to the device substrate 100 may be a flat surface. Thus, in the display apparatus according to the aspect of the present disclosure, the damage of the light-emitting device 500 in each pixel area PA due to the external moisture and impact may be effectively prevented.

Accordingly, the display apparatus according to the aspect of the present disclosure may include the pixel driving circuit DC and the light-emitting devices 500 in each pixel area PA, wherein the pixel driving circuit DC electrically connected to the light-emitting device 500 may include the first thin film transistor T1, the second thin film transistor T2 and the storage capacitor Cst, wherein the second gate electrode 223 of the second thin film transistor T2 which is a driving thin film transistor may include the first sub-gate G1 and the second sub-gate G2 disposed side by side between the second drain electrode 225 and the second source electrode 227 of the second thin film transistor T2, and wherein the second sub-gate G2 electrically connected to the first sub-gate G1 may have a different work-function from the first sub-gate G1. Thus, in the display apparatus according to the aspect of the present disclosure, an electric field applied to the second channel region 221c of the second thin film transistor T2 by the second sub-gate G2 may be different from an electric field applied to the second channel region 221 by the first sub-gate G1. That is, in the display apparatus according to the aspect of the present disclosure, the driving current generated by the second thin film transistor T2 may be increased by the second sub-gate G2 having a relatively large work-function, without reducing a length of the second channel region 221. Therefore, in the display apparatus according to the aspect of the present disclosure, deterioration of process efficiency may be minimized, and electric characteristics of the second thin film transistor T2 of each pixel area PA may be improved. And, in the display apparatus according to the aspect of the present disclosure, efficiency and reliability of the pixel driving circuit DC in each pixel area PA may be improved.

Referring to FIGS. 5 and 6, in the display apparatus according to the aspect of the present disclosure, an electric field applied to the second channel region 221c of the second semiconductor pattern 221 may be not significantly changed, but a driving current generated by the second thin film transistor T2 may be continuously increased, when the work-function ratio G1/G2 of the first sub-gate G1 and the second sub-gate G2 is 1.2 or more. That is, in the display apparatus according to the aspect of the present disclosure, graphs of FIGS. 5 and 6 may be interpreted that electric charges are accumulated in the second gate insulating layer 122, when the work-function ratio G1/G2 of the first sub-gate G1 and the second sub-gate G2 is 1.2 or more. In a general thin film transistor, when electric charges are excessively accumulated in a gate insulating layer, a threshold voltage may be decreased and possibility of leakage current may be increased. Thus, in the display apparatus according to the aspect of the present disclosure, the work-function ratio G1/G2 of the first sub-gate G1 and the second sub-gate G2 in each pixel area PA may be 1.2 or less. Therefore, in the display apparatus according to the aspect of the present disclosure, the difference in characteristics of the second thin film transistors T2, which are a driving thin film transistor may be prevented, and reliability of the pixel driving circuit DC in each pixel area PA may be effectively improved.

In the display apparatus according to the aspect of the present disclosure, the sum of a length of the second sub-channel 221c2 and a length of the third sub-channel 221c3 may be a same as a length of the first sub-channel 221c1. The length of the third sub-channel 221c3 may be a same as the length of the second sub-channel 221c2. For example, in the display apparatus according to the aspect of the present disclosure, the length of the second sub-channel 221c2 and the length of the third sub-channel 221c3 may be half of the length of the first sub-channel 221c1. Thus, in the display apparatus according to the aspect of the present disclosure, an electric field applied to the second channel region 221c of the second semiconductor pattern 221 may be effectively reduced by the second sub-gate G2 having a relatively large work-function.

The display apparatus according to the aspect of the present disclosure is described that the pixel driving circuit DC of each pixel area PA may consist of the first thin film transistor T1, the second thin film transistor T2 and the storage capacitor Cst. However, in the display apparatus according to another aspect of the present disclosure, the pixel driving circuit DC of each pixel area PA may include a driving thin film transistor and at least one switching thin film transistor. For example, in the display apparatus according to another aspect of the present disclosure, the pixel driving circuit DC of each pixel area PA may include the first thin film transistor T1, the second thin film transistor T2, the storage capacitor Cst and a third thin film transistor. The third thin film transistor of each pixel area PA may be a switching thin film transistor to initialize the storage capacitor Cst of the corresponding pixel area PA according to the gate signal. For example, the third thin film transistor of each pixel area PA may include a third gate electrode electrically connected to the corresponding gate line GL, a third drain electrode electrically connected to the initial line applying an initial signal, and a third source electrode electrically connected to the corresponding storage capacitor Cst. Thus, in the display apparatus according to another aspect of the present disclosure, the degree of freedom in configuration of each pixel driving circuit DC may be improved.

In the display apparatus according to the aspect of the present disclosure, the location and the electric connection of the first drain electrode 215, the first source electrode 217, the second drain electrodes 225 and the second source electrode 227 in each pixel driving circuit DC may vary depending on the configuration of the corresponding pixel driving circuit DC and/or the type of the corresponding thin film transistors T1 and T2. For example, in the display apparatus according to another aspect of the present disclosure, the second gate electrode 223 of each pixel driving circuit DC may be electrically connected to the first drain electrode 215 of the corresponding pixel driving circuit DC. Thus, in the display apparatus according to another aspect of the present disclosure, the degree of freedom in the configuration of each pixel driving circuit DC and the type of each thin film transistor T1 and T2 may be improved.

The display apparatus according to the aspect of the present disclosure is described that the first semiconductor pattern 211 and the second semiconductor pattern 221 of each pixel area PA may be made of an oxide semiconductor. However, in the display apparatus according to another aspect of the present disclosure, the second semiconductor pattern 221 of each pixel area PA may include a different material from the first semiconductor pattern 211 of the corresponding pixel area PA. For example, in the display apparatus according to another aspect of the present disclosure, the first semiconductor pattern 211 of each pixel area PA may include low-temperature poly-Si (LTPS). The first thin film transistor T1 of each pixel area PA may be formed to have a same structure as the circuit thin film transistor 290. For example, the first semiconductor pattern 211 of each pixel area PA may be disposed between the lower buffer layer 110 and the first gate insulating layer 121, and the first gate electrode 213 of each pixel area PA may be disposed between the first gate insulating layer 121 and the lower interlayer insulating layer 130. In the display apparatus according to another aspect of the present disclosure, the first light-blocking pattern 310 of each pixel area PA may not be formed. Thus, in the display apparatus according to another aspect of the present disclosure, the degree of freedom in the configuration of each pixel driving circuit DC and the type of each thin film transistor T1 and T2 may be improved.

The display apparatus according to the aspect of the present disclosure is described that the upper planarization layer 180 may include a same material as the lower planarization layer 170. However, in the display apparatus according to another aspect of the present disclosure, the upper planarization layer 180 may include a different material from the lower planarization layer 170. Thus, in the display apparatus according to another aspect of the present disclosure, a thickness difference due to the pixel driving circuit DC of each pixel area PA and the circuit thin film transistor 190 may be effectively removed.

The display apparatus according to the aspect of the present disclosure is described that the first sub-gate G1 and the second sub-gate G2 may include a metal. However, in the display apparatus according to another aspect of the present disclosure, at least one of the first sub-gate G1 and the second sub-gate G2 may include a conductive oxide, such as ITO and IZO. For example, in the display apparatus according to another aspect of the present disclosure, the first sub-gate G1 may have a single-layer structure made of a metal, and the second sub-gate G2 may have a multi-layer structure in which a layer made of a metal and a layer made of a conductive oxide are stacked. Thus, in the display apparatus according to another aspect of the present disclosure, the work-function ratio G1/G2 of the first sub-gate G1 and the second sub-gate G2 may be effectively adjusted. Therefore, in the display apparatus according to another aspect of the present disclosure, efficiency and reliability of the pixel driving circuit DC in each pixel area PA may be improved.

The display apparatus according to the aspect of the present disclosure is described that the amount of oxygen contained in the second sub-channel 221c2 and the amount of oxygen contained in the third sub-channel 221c3 may be a same as the amount of oxygen contained in the first sub-channel 221c1. However, in the display apparatus according to another aspect of the present disclosure, a resistance of the second sub-channel 221c2 and a resistance of the third sub-channel 221c3 may be different from a resistance of the first sub-channel 221c1. For example, in the display apparatus according to another aspect of the present disclosure, the second sub-channel 221c2 may have a resistance between the second drain region 221d and the first sub-channel 221c1, and the third sub-channel 221c3 may have a resistance between the first sub-channel 221c1 and the second source region 221s. The second drain region 221d, the second sub-channel 221c2, the third sub-channel 221c3 and the second source region 221s may include conductive impurities. For example, in the display apparatus according to another aspect of the present disclosure, the second sub-channel 221c2 and the third sub-channel 221c3 may be doped at a low concentration with conductive impurities, and the second drain region 221d and the second source region 221s may be doped at a high concentration with conductive impurities. Thus, in the display apparatus according to another aspect of the present disclosure, deterioration in characteristics of the second thin film transistor T2 due to a hot carrier effect between the second drain region 221d and the first sub-channel 221c1 and between the first sub-channel 221c1 and the second source region 221s may be effectively prevented.

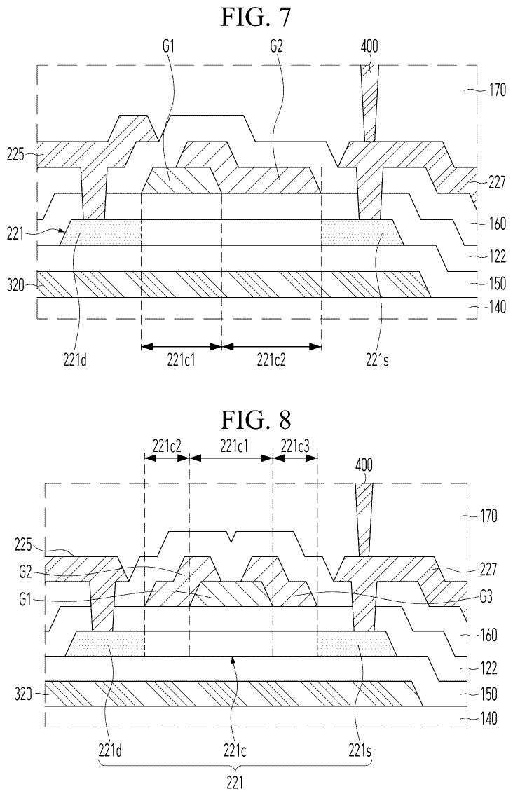

The display apparatus according to the aspect of the present disclosure is described that the second channel region 221c of the second semiconductor pattern 221 may include the first sub-channel 221c1, the second sub-channel 221c2 and the third sub-channel 221c3. However, in the display apparatus according to another aspect of the present disclosure, the second channel region 221c of the second semiconductor pattern 221 may include at least of two sub-channels. For example, in the display apparatus according to another aspect of the present disclosure, the second semiconductor 221 may include a first sub-channel 221c1 between the second drain region 221d and the second source region 221s and a second sub-channel 221c2 between the first sub-channel 221c1 and the second source region 221s, as shown in FIG. 7. The second sub-gate G2 may include an end on the upper surface of the first sub-gate G1. For example, the first sub-gate G1 may include a region directly contacting the upper interlayer insulating layer 160. Thus, in the display apparatus according to another aspect of the present disclosure, an electric field between the first sub-channel 221c1 and second sub-channel 221c2 of each pixel area PA may be changed by difference in the work-function between the first sub-gate G1 and the second sub-gate G2 of the corresponding pixel area PA. For example, in the display apparatus according to another aspect of the present disclosure, speed of electrons accelerated in a channel formed in the second sub-channel 221c2 by the second sub-gate G2 having a relatively large work-function may be reduced by a channel formed in the first sub-channel 221c1 by the first sub-gate G1 having a relatively small work-function. Therefore, in the display apparatus according to another aspect of the present disclosure, deterioration in characteristics of the second thin film transistor due to a hot carrier effect between the second drain region 221d and the second source region 221s may be prevented.

In the display apparatus according to another aspect of the present disclosure, a length of the second sub-channel 221c2 may be different from a length of the first sub-channel 221c1. For example, the second sub-channel 221c2 may have a longer length than the first sub-channel 221c1. The speed and the energy of electrons moving toward the second drain region 221d from the second source region 221s may be proportional to the length of the second sub-channel 221c2. That is, in the display apparatus according to another aspect of the present disclosure, a driving current generated by the second thin film transistor may be maximized by adjusting a relative length of the first sub-channel 221c1 and the second sub-channel 221c2, without deterioration in characteristics of the second thin film transistor. Therefore, in the display apparatus according to another aspect of the present disclosure, the efficiency of the pixel driving circuit in each pixel area may be maximized.

The display apparatus according to the aspect of the present disclosure is described that a channel of the second sub-channel 221c2 and a channel of the third sub-channel 221c3 may be formed by the second sub-gate G2. However, in the display apparatus according to another aspect of the present disclosure, the second gate electrode may include a first sub-gate G1 overlapping with the first sub-channel 221c1, a second sub-gate G2 overlapping with the second sub-channel 221c2 and a third sub-gate G3 overlapping with the third sub-channel 221c3, as shown in FIG. 8. The third sub-gate G3 may be spaced apart from the second sub-gate G2. The third sub-gate G3 may be electrically connected to the first sub-gate G1 and the second sub-gate G2. For example, a first side of the first sub-gate G1 may be in direct contact with the second sub-gate G2 and a second side of the first sub-gate G1 may in direct contact with the third sub-gate G3.

The third sub-gate G3 may have a larger work-function than the first sub-gate G1. For example, a work-function of the third sub-gate G3 may be a same as a work-function of the second sub-gate G2. The third sub-gate G3 may include a same material as the second sub-gate G2. The third sub-gate G3 may be formed by a same process as the second sub-gate G2. For example, the third sub-gate G3 may be formed simultaneously with the second sub-gate G2. Thus, in the display apparatus according to another aspect of the present disclosure, the degree of freedom for the second gate electrode in each pixel area may be improved.

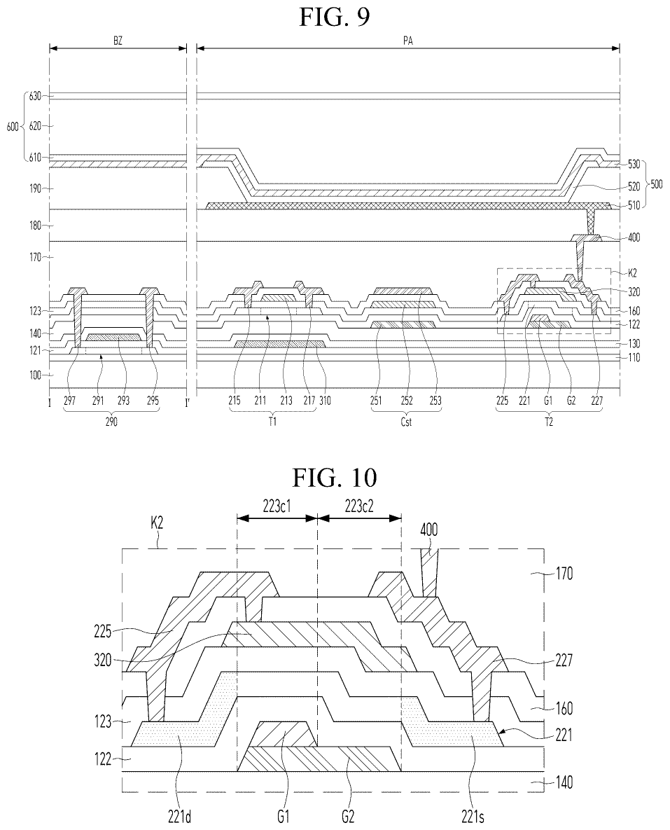

The display apparatus according to the aspect of the present disclosure is described that the second semiconductor pattern 221 of each pixel area PA may be disposed between the device substrate 100 and the second gate electrode 223 of the corresponding pixel area PA. However, in the display apparatus according to another aspect of the present disclosure, a structure of the second thin film transistor T2 in each pixel area PA may be different from a structure of the first thin film transistor T1 in the corresponding pixel area PA. For example, in the display apparatus according to another aspect of the present disclosure, the first semiconductor pattern 211 of each pixel area PA may be disposed between the device substrate 100 and the first gate electrode 213 of the corresponding pixel area PA, and the first sub-gate G1 and the second sub-gate G2 of each pixel area PA may be disposed between the device substrate 100 and the second semiconductor pattern 221 of the corresponding pixel area PA, as shown in FIGS. 9 and 10. The second gate insulating layer 122 may be disposed between the first sub-gate G1 and the second semiconductor pattern 221 of each pixel area PA and between the second sub-gate G2 and the second semiconductor pattern 221 of each pixel area PA. For example, the first sub-gate G1 may be disposed between a portion of the second sub-gate G2 and the second gate insulating layer 122. The first gate electrode 213 of each pixel area PA may be insulated from the first semiconductor pattern 211 of the corresponding pixel area PA by a third gate insulating layer 123. For example, the first semiconductor pattern 211 and the second semiconductor pattern 221 of each pixel area PA may be covered by the third gate insulating layer 123. The first gate electrode 213 of each pixel area PA may be disposed on the third gate insulating layer 123. The third gate insulating layer 123 may include an insulating material. For example, the third gate insulating layer 123 may include an inorganic insulating material, such as silicon oxide (SiOx) and silicon nitride (SiNx). The third gate insulating layer 123 may be in direct contact with the second gate insulating layer 122 at the outside of the first semiconductor pattern 211 and the second semiconductor pattern 221 in each pixel area PA. The third gate insulating layer 123 may include a same material as the second gate insulating layer 122. For example, an interface between the second gate insulating layer 122 and the third gate insulating layer 123 may not be recognized. The upper interlayer insulating layer 160 may be disposed between the third gate insulating layer 123 and the lower planarization layer 170. Thus, in the display apparatus according to another aspect of the present disclosure, the malfunction of the second thin film transistor T2 in each pixel area PA may be prevented, and the driving current generated by the second thin film transistor T2 of each pixel area PA may be increased, regardless of a structure of the second thin film transistor T2 in each pixel area PA. Therefore, in the display apparatus according to another aspect of the present disclosure, the efficiency and the reliability of the pixel driving circuit in each pixel area PA may be improved. And, in the display apparatus according to another aspect of the present disclosure, lower power driving may be possible, and power consumption may be reduced.

The second light-blocking pattern 320 of each pixel area PA may be disposed between the third gate insulating layer 123 and the upper interlayer insulating layer 160. For example, the second light-blocking pattern 320 of each pixel area PA may be disposed on a same layer as the first gate electrode 213 of the corresponding pixel area PA. The second light-blocking pattern 320 of each pixel area PA may include a same material as the first gate electrode 213 of the corresponding pixel area PA. The second light-blocking pattern 320 of each pixel area PA may be formed by a same process as the first gate electrode 213 of the corresponding pixel area PA. For example, the second light-blocking pattern 320 of each pixel area PA may be formed simultaneously with the first gate electrode 213 of the corresponding pixel area PA. Thus, in the display apparatus according to another aspect of the present disclosure, characteristics deviation of the second thin film transistor T2 in each pixel area PA due to the external light and the light emitted from the light-emitting device 500 of the corresponding pixel area PA may be prevented. Therefore, in the display apparatus according to another aspect of the present disclosure, the efficiency and the reliability of the pixel driving circuit in each pixel area PA may be effectively improved.

The storage capacitor Cst of each pixel area PA may include a first capacitor electrode 251 disposed on a same layer as the second sub-gate G2, a second capacitor electrode 252 disposed on a same layer as the second light-blocking pattern 320, and a third capacitor electrode 253 disposed on a same layer as the second source electrode 227. Thus, in the display apparatus according to another aspect of the present disclosure, an area occupied by the storage capacitor Cst of each pixel area PA may be minimized, without deterioration of process efficiency.

In the result, the display apparatus according to the aspects of the present disclosure may comprise the pixel driving circuit electrically connected to the light-emitting device, wherein the pixel driving circuit may include a driving thin film transistor and at least one switching thin film transistor, wherein a driving gate electrode of the driving thin film transistor may have at least two work-function. Thus, in the display apparatus according to the aspects of the present disclosure, the malfunction of the driving thin film transistor may be prevented, and the driving current generated by the driving thin film transistor may be increased. That is, in the display apparatus according to the aspects of the present disclosure, the electrical characteristics of the driving thin film transistor may be improved. Thereby, in the display apparatus according to the aspects of the present disclosure, the efficiency and the reliability of the pixel driving circuit may be improved. And, in the display apparatus according to the aspects of the present disclosure, power consumption may be reduced by lower power driving.

It will be apparent to those skilled in the art that various modifications and variations can be made in the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display apparatus comprising:
a pixel driving circuit including a thin film transistor; and
a light-emitting device electrically connected to the pixel driving circuit,
wherein a gate of the thin film transistor includes a first sub-gate and a second sub-gate electrically connected to the first sub-gate,
wherein the thin film transistor has a semiconductor pattern that includes a first sub-channel and a second sub-channel, which are disposed parallel to each other between a drain region and a source region, and
wherein the second sub-gate overlapping the second sub-channel has a work-function greater than the first sub-gate overlapping the first sub-channel.

2. The display apparatus according to claim 1, wherein the work-function ratio of the first sub-gate and the second sub-gate is 1.2 or less.

3. The display apparatus according to claim 1, wherein the second sub-channel is disposed between the drain region and the first sub-channel.

4. The display apparatus according to claim 3, wherein the second sub-channel has a same resistance as the first sub-channel.

5. The display apparatus according to claim 3, wherein the gate electrode includes a third sub-gate having a work-function greater than the first sub-gate,
wherein the semiconductor pattern includes a third sub-channel overlapping the third sub-gate, and
wherein the first sub-channel is disposed between the second sub-channel and the third sub-channel.

6. The display apparatus according to claim 5, wherein the third sub-gate has a same work-function as the second sub-gate.

7. The display apparatus according to claim 1, wherein the first sub-gate and the second sub-gate include a metal.

8. The display apparatus according to claim 1, further comprising a device substrate supporting the pixel driving circuit and the light-emitting device,
wherein the first sub-gate and the second sub-gate are disposed between the device substrate and the semiconductor pattern.

9. A display apparatus comprising:
a first thin film transistor disposed on a pixel area of a device substrate, wherein the first thin film transistor includes a first semiconductor pattern and a first gate electrode;
a second thin film transistor disposed on the pixel area of the device substrate, wherein the second thin film transistor includes a second semiconductor pattern and a second gate electrode; and
a light-emitting device disposed on the pixel area of the device substrate, the light-emitting device electrically connected to the second thin film transistor,
wherein the second semiconductor pattern includes a first sub-channel and a second sub-channel disposed side by side between a drain region and a source region,
wherein the second gate electrode includes a first sub-gate overlapping the first sub-channel and a second sub-gate overlapping the second sub-channel, and
wherein an electric field applied to the first sub-channel by the first sub-gate is different from an electric field applied to the second sub-channel by the second sub-gate electrically connected to the first sub-gate.

10. The display apparatus according to claim 9, wherein the first semiconductor pattern and the second semiconductor pattern include an oxide semiconductor.

11. The display apparatus according to claim 9, wherein a distance between the second sub-channel and the second sub-gate is a same as a distance between the first sub-channel and the first sub-gate.

12. The display apparatus according to claim 11, wherein the second sub-gate is in contact with a side surface of the first sub-gate.

13. The display apparatus according to claim 9, wherein the second sub-gate includes a different material from the first sub-gate.

14. The display apparatus according to claim 13, wherein the first gate electrode includes a same material as the first sub-gate.

15. The display apparatus according to claim 9, wherein the second sub-channel has a length different from a length of the first sub-channel.
